(19) United States
(12) Patent Application Publication
(10) Pub. No.: US 2009/0219102 A1
(43) Pub. Date: Sep. 3, 2009

(54) STABILIZED ELECTRICAL OSCILLATORS WITH NEGATIVE RESISTANCE

(76) Inventor: ERIC R. EHLERS, Santa Rosa, CA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 12/040,197

(22) Filed: Feb. 29, 2008

(51) Int. Cl. H03B 7/00

(52) U.S. Cl. 331/115

(57) ABSTRACT

An electrical oscillator includes a first oscillating transistor and a second oscillating transistor. The electrical oscillator also includes a first non-linear load connected to a terminal of the first oscillating transistor, and a second non-linear load connected to a terminal of the second oscillating transistor. The electrical oscillator also includes a negative resistance generated between the terminal of the first oscillating transistor and the terminal of the second oscillating transistor. The electrical oscillator does not include a tunable resonator.

### BACKGROUND

Electrical oscillators are used in digital systems, communications systems and electronic test equipment, to name only a few applications. One type of electrical oscillator is known as a voltage controlled oscillator (VCO). A VCO is a component that can be used to translate DC voltage into a time dependent voltage or signal. In general, VCOs are tunable oscillators designed to produce an oscillating signal of a particular frequency ‘f’ corresponding to a given tuning voltage. The frequency of the oscillating signal is dependent upon the magnitude of a tuning voltage applied to the oscillator. The frequency ‘f’ may be varied from fₘᵢₙ to fₘₐₓ and these limits are referred as the tuning range or bandwidth of the VCO. For many applications, particularly for test instrumentation and communication systems, a comparably wide tuning range is beneficial.

Many VCOs incorporate varactors, which are reverse biased diodes that function as voltage controlled capacitors, as the tuning mechanism. Varactors are comparably small, low cost, use negligible bias power and are available as integration elements in some semiconductor processes. Varactors are used in conjunction with fixed inductors to realize tunable LC resonators. The quality (Q) factor (or simply, Q) of varactors is usually high at low frequencies and degrades as with increasing frequency. While a tuning bandwidth of more than an octave is common in varactor-based VCOs at low frequencies, at microwave frequencies and above (i.e., frequencies greater than about 10 GHz) it is difficult to achieve a tuning bandwidth of more than one octave. Thus, the tuning range can be undesirably limiting.

As is known, varactor-tuned VCOs have modest phase noise at microwave frequencies. When lower phase noise is required, tunable high-Q Yttrium-Iron-Garnet (YIG) resonators are often used. Alternatively, when low phase noise is not a requirement, multivibrator VCOs can be used. Multivibrators do not include tunable resonators, but rely on varying the current charging a fixed capacitor to tune the oscillation frequency. There are two main advantages in using a multibrator. First, multivibrators do not require varactors, which simplifies the circuit and makes multivibrators suitable for integration in semiconductor processes that do not have varactors. Second, they have very wide tuning range, typically multi-octave.

While multivibrator-based VCOs have a greater tuning range than varactor-based VCOs, their tuning range can nonetheless be limited at high frequencies due to non-ideal behavior of the active devices. For example, transistors become less unilateral and their gain decreases with frequency (due to parasitic transistor elements), preventing multivibrators from achieving a wide tuning range.

Another disadvantage of many known VCOs is that the oscillation amplitude is typically established by the limiting action of the non-linear active device characteristics, which for some bipolar transistors can cause the transistor to operate in an unreliable saturation mode.

There is a need, therefore, for electrical oscillators, including VCOs that overcome at least the shortcoming of known oscillators described above.

### SUMMARY

In accordance with a representative embodiment, an electrical oscillator includes a first oscillating transistor and a second oscillating transistor. The electrical oscillator also includes a first non-linear load connected to a terminal of the first oscillating transistor and a second non-linear load connected to a terminal of the second oscillating transistor. The electrical oscillator also includes a negative resistance generated between the terminal of the first oscillating transistor and the terminal of the second oscillating transistor, wherein the electrical oscillator does not include a tunable resonator.

In accordance with another representative embodiment, a voltage controlled oscillator (VCO) includes a first oscillating transistor and a second oscillating transistor. The VCO also includes a first non-linear load connected to a terminal of the first oscillating transistor and a second non-linear load connected to a terminal of the second oscillating transistor. The VCO also includes a negative resistance generated between the terminal of the first oscillating transistor and the terminal of the second oscillating transistor, wherein the VCO does not include a tunable resonator.

### BRIEF DESCRIPTION OF THE DRAWINGS

The present teachings are best understood from the following detailed description when read with the accompanying drawing figures. The features are not necessarily drawn to scale. Wherever practical, like reference numerals refer to like features.

FIG. 1 is a simplified schematic diagram of an electrical oscillator in accordance with a representative embodiment.

FIG. 2 is a simplified schematic diagram of an electrical oscillator in accordance with a representative embodiment.

FIG. 3 is a graphical representation of a reflection coefficient showing negative resistance as a function of frequency and collector load of an electrical oscillator in accordance with a representative embodiment.

FIG. 4 is a graphical representation of a reflection coefficient showing negative resistance as a function of frequency and collector load of an electrical oscillator in accordance with a representative embodiment.

FIG. 5 is a graphical representation of output frequency versus tuning voltage of an electrical oscillator in accordance with a representative embodiment.

### DEFINED TERMINOLOGY

It is to be understood that the terminology used herein is for purposes of describing particular embodiments only, and is not intended to be limiting.

As used in the specification and appended claims, the terms ‘a’, ‘an’ and ‘the’ include both singular and plural referents, unless the context clearly dictates otherwise. Thus, for example, ‘a device’ includes one device and plural devices.

As used in the specification and appended claims, the term tunable resonator includes a resonator tuned thermally, mechanically, electrically or magnetically. Examples of such tunable resonators include, but are not limited to: varactors, YIG resonators, cavity-tuned resonators and dielectric resonant oscillators (DROs).

### DETAILED DESCRIPTION

In the following detailed description, for purposes of explanation and not limitation, representative embodiments disclosing specific details are set forth in order to provide a thorough understanding of the present teachings. Descriptions of known systems, devices, materials, methods of operation and methods of manufacture may be omitted so as to avoid obscuring the description of the example embodiments. Nonetheless, systems, devices, materials and methods that are within the purview of one of ordinary skill in the art may be used in accordance with the representative embodiments.

As described more fully herein, the representative embodiments relate generally to electrical oscillators having oscillating transistors, with a terminal loads comprising a negative resistance. As will become clearer as the present description continues, the negative resistance may be a differential negative resistance. Frequency tuning of the oscillating transistors comprises varying an impedance of a positive feedback connection. While the embodiments are described primarily in connection with VCOs, electrical oscillators in general are contemplated. For example, rather than varying the impedance of a positive feedback connection via an applied voltage or current, the electrical oscillators of representative embodiments may be tuned by varying the impedance of the terminal (e.g., collector) loads by varying the temperature of the load or by varying the intensity of light shining on the load.

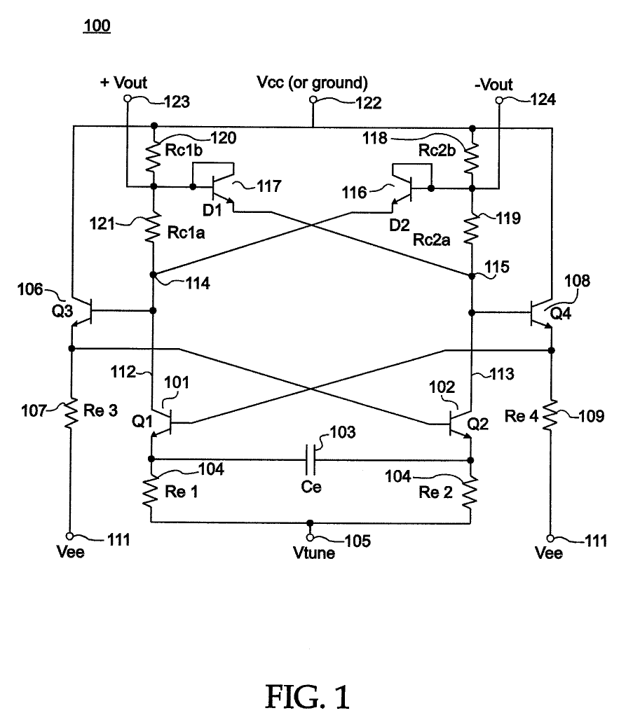

FIG. 1 is a simplified schematic diagram of an electrical oscillator 100 in accordance with a representative embodiment. The oscillator 100 includes a first oscillating transistor 101 (often referred to as ‘transistor 101’ for simplicity) and a second oscillating transistor 102 (often referred to as ‘transistor 102’ for simplicity). As will become clearer as the present description continues, the transistors 101, 102 are substantially identical in performance. An emitter capacitor 103 and emitter resistors 104 are connected to respective emitters of the transistors 101, 102 as shown. An input 105 for a tuning voltage is connected to the emitter resistors 104. The circuit 100 also includes a first emitter-follower transistor 106 and a second emitter-follower transistor 108, with emitter resistors 107 and 109, respectively, connected thereto. Inputs 110 and 111 provide emitter voltages to the emitter follower transistors 106, 108, respectively.

The first oscillating transistor 101 includes a first collector 112 and the second oscillating transistor 102 includes a second collector 113. The first collector 112 is connected to a first tap 114, which in turn is connected to an emitter of a second diode-connected transistor 116. The second collector 113 is connected to a second tap 115, which in turn is connected to an emitter of a first diode connected transistor 117. The first diode-connected transistor 117 and the second diode-connected transistor 116 may alternatively be diodes, and are often referred to below as first diode 117 and second diode 116 for ease of description. As will become clearer as the present description continues, the diodes 116, 117 are substantially identical in performance.

The first diode 117 includes a first collector resistance 118 and a second collector resistance 119 connected differentially as shown. Likewise, the second diode 116 includes a third collector resistance 120 and a fourth collector resistance 121 also connected differentially. Completing the circuit is an input 122 for the collector voltage, which is at ground in the present configuration; and positive output terminal 123 and negative output terminal 124.

The first and second oscillating transistors 101, 102 are illustratively npn InP heterojunction bipolar transistors (HBTs). However, this is merely illustrative, and it is emphasized that other three terminal devices are contemplated by the present teachings to provide oscillation. For instance, HBTs based on other materials (e.g., other III-V semiconductors) may be used. Alternatively, pseudomorphic high electron mobility transistors (pHEMTs) may be used for the first and second oscillating transistors 101, 102. Alternatively, field-effect transistors (FETs) may be used for the first and second oscillating transistors 101, 102. Illustrative FETs include metal-oxide-semiconductor (MOS) FETs may be used. Moreover, metal semiconductor FETs (MESFETs) may be used. Again, a wide variety of materials are available for fabricating the transistors 101, 102, including but not limited to Si, Ge, SiGe, and a variety of III-V semiconductors.

Similarly, as noted above the first and second diodes 116, 117 may be diode-connected transistors or diodes. If diode-connected transistors, the first and second diodes 116, 117 may one of the types of transistors described above with the shorting of two terminals to effect the diode. Alternatively, one of a variety of pn-junction diodes or metal-semiconductor junction (Schottky) diodes may be used for the first and second diodes 116, 117.

Selection of alternative devices (e.g., FETs, pnp transistors) may require modification of parameters, connection, etc. to realize a functioning oscillator. For instance, if a FET is selected, rather than a collector, the drain of the first and second oscillating transistors 101, 102 would be connected to a negative resistance. As such, more generally therefore, a terminal of a three-terminal device is connected to the negative resistance. As one deft in circuit design will appreciate the need for such modifications, these modifications are thus contemplated by the present teachings.

Finally, and as will be appreciated by one of ordinary skill in the art, the fabrication of the circuit 100 in large-scale processing is advantageous. Thus, in certain embodiments employing wafer-scale fabrication, the selection of materials is predicated on the selection of devices for the first and second oscillating transistors 101, 102 is related to the selection of the diodes 116, 117. As such, if one were to select a GaAs-based HBT for transistors 101, 102, the diodes likely would be GaAs-based diodes as well.

In operation, the cross-connection of the first collector 112 to the second diode 116 and the second collector 113 to the first diode 117 as shown results in a differential load at each collector, and a negative resistance. The differential loads of the circuit 100 comprise non-linear terminal (collectors in the presently described embodiments) loads comprising of resistors 118-121 and first and second diodes 117, 116. The connection of the second diode 116 via the tap 114 provides a bias voltage from the first transistor 101 to the second diode 116; and the connection of the first diode 117 via the tap 115 provides a bias voltage from the second transistor 102 to the first diode 117.

In the representative embodiments described in conjunction with FIG. 1, the negative resistance is provided by the connection of the base of the first oscillating transistor 101 to the emitter of the second emitter-follower transistor 108; the connection of the base of the second oscillating transistor 102 to the emitter of the first emitter-follower transistor 107; and the emitter capacitor 103. As will be appreciated, the negative resistance of the representative embodiments, among other things, completes a positive feedback connection.

The non-linear terminal load (e.g., non-linear collector load) of the representative embodiments function as a limiting mechanism for the oscillator. To this end, at lower oscillation amplitudes the closed loop gain of the oscillator 100 is greater than unity (1), which allows the oscillation to start. The limiting action provided by the non-linear terminal loads reduces the gain to unity and the amplitude of oscillation stabilizes at the final oscillation condition. Thus, the non-linear collector loads function as stabilizing limiters since the closed-loop gain decreases as the oscillation amplitude increases.

Decreasing the gain reduces the tendency of the first and second oscillating transistors to oscillate and results in a substantially stable oscillation amplitude. In accordance with the presently described embodiments, the limiting action is manifest as a decrease in resistance across the first and second diode-connected transistors 117, 116 (or alternatively diodes) as the oscillation amplitude increases. As will be appreciated by one of ordinary skill in the art, the limiting action is a function of the voltage across the first and second diode-connected transistors 117, 116; and a function of the DC bias through the first and second diode-connected transistors 117, 116.

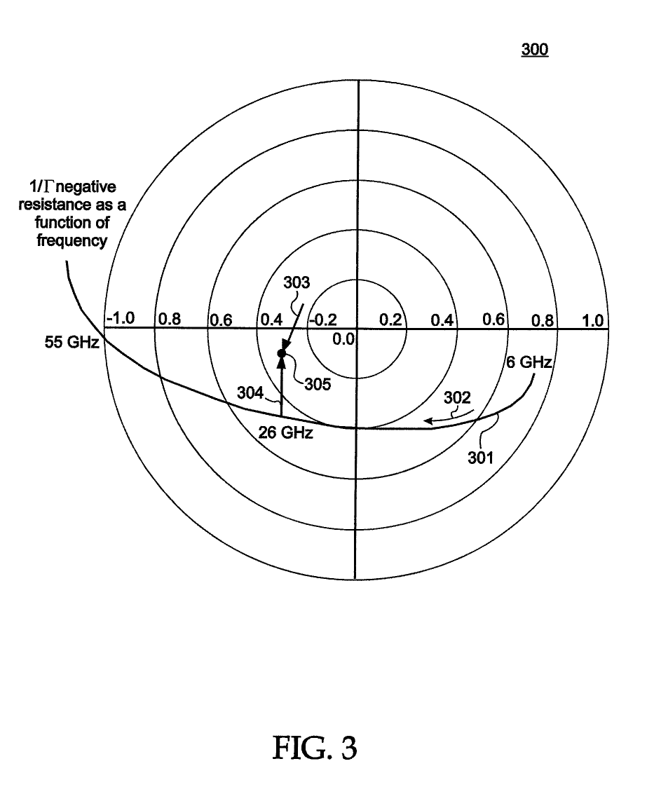

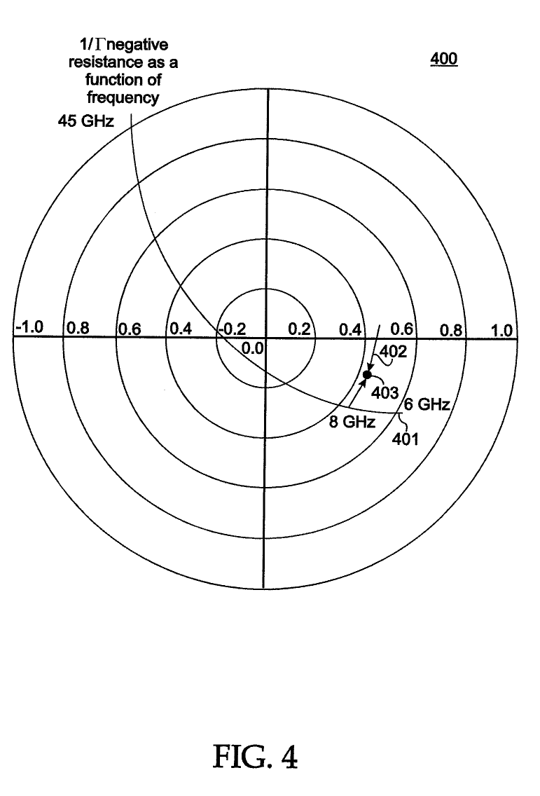

In the presently described embodiments, the voltage across the first and second diodes 117, 116 is illustratively an RF voltage. Increasing the forward DC bias current through the first and second diodes 117, 116 limits oscillation to a lower RF voltage level. Moreover, lowering the load impedance increases the frequency of oscillation (as can be seen by the negative resistance curves in FIGS. 3 and 4 discussed below.) Consequently, the oscillator frequency may be tuned by changing the impedance and thus the DC current through the diodes. Illustratively, the DC current through the first and second diodes 17, 116 may be changed by changing the oscillating transistors' bias or by incorporating a dedicated bias line in the oscillator 100, or both. Thus, the non-linear load (comprised of resistors and first and second diodes 117, 116) functions as both a stabilizing limiter and a frequency tuning mechanism.

Certain clear benefits are provided by the electrical oscillator 100. In a typical oscillator the limiting action is provided by the oscillating transistors. By contrast, in accordance with the representative embodiments, by having a limiting action that does not rely on or otherwise comprise additional or external oscillating transistors, the first and second oscillating transistors 101, 102 can be biased for optimum high frequency operation, or maximum signal-to-noise ratio, or both, without regard to the desired limiting RF amplitude level. Moreover, the first and second oscillating transistors 101, 102 are able to operate in a substantially linear mode which can improve reliability and maintain the loaded Q of the oscillator.

In illustrative embodiments, varying the differential impedance of the cross-connected first and second oscillating transistors 101, 102 and thereby tuning the electrical oscillator 100, involves adjusting the tuning voltage at the input 105. Specifically, as the tuning voltage, Vₜᵤₙₑ, is made more negative, the emitter current increases in the first and second oscillating transistors 101, 102 and the voltage across the second collector resistance 121 and the fourth collector resistance 121 also increases. This increases the forward bias across first and second diodes 117, 116, respectively. As such, as Vₜᵤₙₑ is made more negative, the differential impedance between the collectors of the first and second oscillating transistors 101, 102 decreases due to decreased load impedance and increased capacitance.

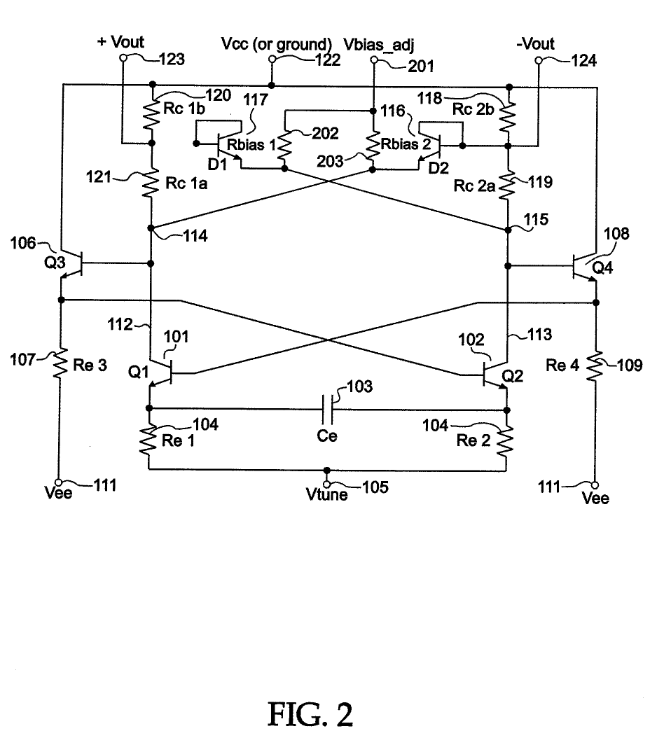

As described above, the tuning of the electrical oscillator 100 is effected by varying the differential impedance presented to the collectors of the cross-connected first and second oscillating transistors 101, 102. In another representative embodiment, an external bias voltage is applied to increase the tuning range of the oscillator. FIG. 2 is a simplified schematic circuit diagram of an electrical oscillator in accordance with a representative embodiment and includes an external bias input 201. Many of the components described in connection with the representative embodiments of FIG. 1 and their function are substantially identical. As such, details are not duplicated, but rather differences are described.

The input 201 provides a bias voltage, V_{bias}_{_{—}}_{adjust}, which biases the first and second diodes 117, 116 through a first bias resistor 202 and a second bias resistor 203, respectively. With this control there is additional flexibility in adjusting the oscillation frequency. In particular, the oscillation frequency and amplitude may be controlled by setting the bias of the first and second diodes 117, 116 as described previously. If greater frequencies of oscillation are desired, a greater bias on the first and second diodes 117, 116 will increase the oscillation frequency by increasing the current and thereby decreasing the differential impedance between the first and second collectors 112, 113. Moreover, control of the amplitude by gain reduction is also realized. With this arrangement, a substantially optimum transistor bias can be established at each frequency. This prevents the transistor bias from dropping too low (with a consequent drop in gain and negative resistance) or too high (with a consequent operation at a high junction temperature). With this added bias control the tuning range can be increased over what can be achieved with the variation of the differential impedance described in connection with the embodiments of FIG. 1.

As will be appreciated, in the embodiments described in connection with FIGS. 1 and 2, the oscillation frequency of the oscillating transistors are controlled by controlling the load impedance of the terminal (e.g., collector) loads by controlling the voltage/current to the diodes 116, 117. As alluded to previously, frequency tuning of the oscillating transistors 101, 102 by varying an impedance of a positive feedback connection may be effected by means other than voltage/current variation. In accordance with an illustrative embodiment, rather than diode 116, 117 (or diode connected transistors), a thermistor (not shown) may be connected to each terminal (e.g., each collector 112, 113) to provide the terminal load. Because the diodes 116, 117 are foregone, the resistors required for biasing would not be needed. By varying the temperature of the thermistors, the load impedance varies as needed to tune the oscillating transistors 101, 102. Notably, the limiting function of the oscillating transistors is provided by the thermistors, which provide increasing power as the impedance drops.

In accordance with another representative embodiment, a photoresistor (not shown) or similar light-dependent resistor (not shown) could supplant the diodes 116, 117. Variation of the intensity of light directed to the photoresistor will result in a variation of the impedance at the terminals (e.g., collectors 112, 113). Like the thermistors, the photoresistors provide the limiting function that reduces the impedance with increasing power. Still other devices and configurations for frequency tuning of the oscillating transistors 101, 102 by varying an impedance of a positive feedback connection within the purview of one of ordinary skill in the art are contemplated.

FIG. 3 is a graphical representation of a reflection coefficient showing negative resistance as a function of frequency and collector load of an electrical oscillator in accordance with a representative embodiment. The electrical oscillator may be electrical oscillator 100 or electrical oscillator 200, having components described in conjunction with representative embodiments above. The graphical representation of FIG. 3 may be derived from a circuit model comprising the electrical oscillator 100 or the electrical oscillator 200 as a negative resistance connected to a load. Such a technique for modeling the oscillators 100, 200 is known to those skilled in the art of high-frequency circuit design and, as such, details of the method of modeling the oscillators 100, 200 are omitted to avoid obscuring the present teachings. Curve 301 is the graph of negative resistance (1/Γ<1) versus frequency (referred to as negative resistance curve 301) over an illustrative frequency range of oscillation of approximately 6.0 GHz to approximately 55 GHz. As will be appreciated from a review of negative resistance curve 301, there is a broadband negative resistance generated between the collectors (or terminals depending on the type of oscillating transistor selected) due to their respective positive feedback connection. The arrow 302 indicates the variation of the negative resistance with oscillation frequency for a particular bias condition of the first and second oscillating transistors 101, 102, and consequently the first and second diodes 117, 116.

However, the negative resistance curve 301 is a function of collector voltage and will ‘move’ toward the ordinate (in an ‘upward’ direction 303) towards the top of the polar plot as the amplitude of oscillation increases. The model shown in FIG. 3 represents an oscillator having a relatively high emitter current first and second oscillating transistors 101, 102 operating at a greater (in this example negative) Vₜᵤₙₑ voltage and corresponding the negative resistance and diode load. Under these conditions, the impedance seen by the collectors 112, 113 of the first and second oscillating transistors 101, 102, respectively, is comparatively low. As the amplitude of oscillation increases, the negative resistance curves moves up and the collector load impedance decreases (moves in the direction 304 due to lower resistance and increased capacitance). A stable oscillation will occur when the negative resistance curve 301 moves upward and intersects the reflection coefficient of the load (Γ_{collector load}). At the intersection, a stable oscillation point 305 exists where the feedback in the oscillator is unity with zero phase shift. In the present illustration, the negative resistance curve and the load impedance coincide at a stable oscillation condition as shown with a frequency in this example of 26 GHz.

FIG. 4 is a graphical representation of a reflection coefficient showing negative resistance as a function of frequency and collector load of an electrical oscillator in accordance with a representative embodiment. The electrical oscillator may be electrical oscillator 100 or electrical oscillator 200, having components described in conjunction with representative embodiments above. The electrical oscillator is modeled according to the method described in connection with FIG. 3. In the present example, a lower frequency oscillation condition is realized. Curve 401 shows the negative resistance curve over a frequency range of approximately 6 GHz to approximately 40 GHz. In the present model, the tuning voltage (Vₜᵤₙₑ) has a lesser magnitude (i.e., less negative) and a comparatively low emitter current. In this case the negative resistance and load curves are for the first and second oscillating transistors 101, 102. Under these conditions the impedance seen by the collectors 112, 113 of the first and second oscillating transistors 101, 102 is relatively high. As the oscillation amplitude increases, the negative resistance curve 401 moves upwardly and a load impedance decreases (moves in a direction 402 due to lower resistance and increased capacitance) intersect at a stable oscillation condition at point 403 at a lower frequency of 8 GHz.

The negative resistance curves 301, 401 are functions of oscillation frequency and the oscillation frequency depends on the value of the collector load impedance FIGS. 3 and 4 show that the negative resistance of the respective models decreases with increasing amplitude and the impedance of the load from diodes 116, 117 also drops with increasing amplitude until a stable oscillation condition is reached (with a closed loop gain of 1). Lowering the impedance of the load decreases the gain which reduces the tendency to oscillate and leads to a stable oscillation amplitude.

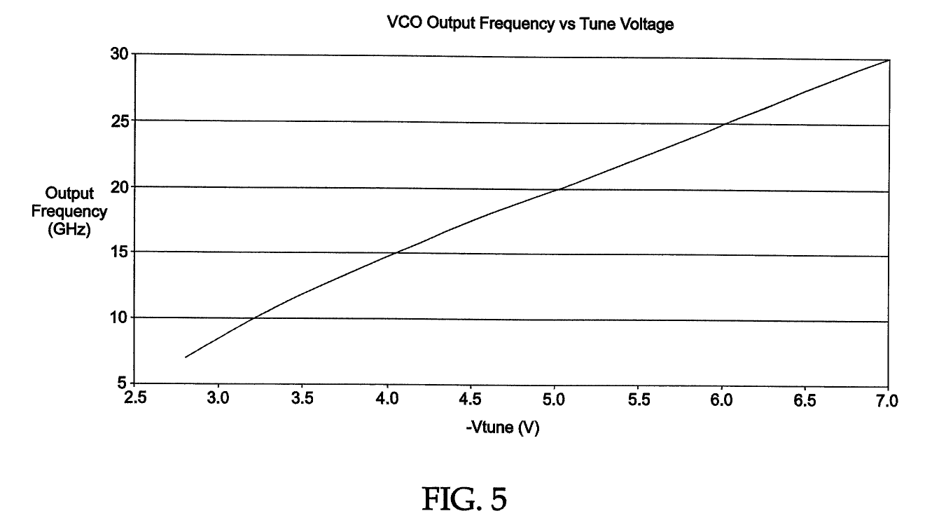

FIG. 5 is a graphical representation of output frequency versus tuning voltage of an electrical oscillator in accordance with a representative embodiment. The oscillator may be electrical oscillator 100 or electrical oscillator 200 described previously, with selected devices and component values. In a representative embodiment, the first and second oscillating transistors 101, 102 were HBTs with a transition frequency (Fₜ) of approximately 180 GHz. The measured oscillation frequency curve 601 reveals an oscillation frequency range from a low end of approximately 6 GHz to approximately 30 GHz over a tuning voltage range of approximately −2.75 V to approximately −7.0 V.

In view of this disclosure it is noted that variations to the electrical oscillators and VCOs described herein can be implemented in keeping with the present teachings. Further, the various topologies, devices, components, materials, structures and parameters are included by way of illustration and example only and not in any limiting sense. In view of this disclosure, those skilled in the art can implement the present teachings in determining their own applications and needed components, materials, structures and equipment to implement these applications, while remaining within the scope of the appended claims.

1. An electrical oscillator, comprising:
a first oscillating transistor and a second oscillating transistor;
a first non-linear load connected to a terminal of the first oscillating transistor;
a second non-linear load connected to a terminal of the second oscillating transistor; and
a negative resistance generated between the terminal of the first oscillating transistor and the terminal of the second oscillating transistor, wherein the electrical oscillator does not include a tunable resonator.

2. An electrical oscillator as claimed in claim 1, wherein the tunable resonator is one of: a varactor, a YIG resonator, a cavity-tuned resonator and a dielectric resonant oscillator (DRO).

3. An electrical oscillator as claimed in claim 2, wherein the first non-linear load comprises a diode.

4. An electrical oscillator as claimed in claim 1, wherein the second non-linear load comprises a diode.

5. An electrical oscillator as claimed in claim 1, wherein the first non-linear load comprises a diode-connected transistor.

6. An electrical oscillator as claimed in claim 1, wherein the second non-linear load comprises a diode-connected transistor.

7. An electrical oscillator as claimed in claim 1, wherein the terminals are respective collectors of the first and second oscillating transistors.

8. An electrical oscillator as claimed in claim 1, wherein the terminals are respective drains of the first and second oscillating transistors.

9. An electrical oscillator as claimed in claim 1, wherein each of the non-linear loads comprise resistors configured to provide a differential output impedance at the respective collectors or the respective drains of the first and the second oscillating transistors.

10. An electrical oscillator as claimed in claim 1, wherein the negative resistance comprises a differential negative resistance having a cross-coupled diode and resistor load.

11. An electrical oscillator as claimed in claim 1, wherein the negative resistance is adapted to stabilize oscillation by reducing a closed-loop gain of the oscillator with an increasing amplitude of oscillation.

12. An electrical oscillator as claimed in claim 1, wherein the first non-linear load has a first impedance, which varies with a change in a bias current of the first oscillating transistor and a change in a dedicated bias connection.

13. An electrical oscillator as claimed in claim 1, wherein the second non-linear load has a second impedance, which varies with a change in a bias current of the second oscillating transistor and a change in a dedicated bias connection.

14. A voltage controlled oscillator (VCO), comprising:
a first oscillating transistor and a second oscillating transistor;
a first non-linear load connected to the terminal of the first oscillating transistor;
a second non-linear load connected to the terminal of the second oscillating transistor; and
a negative resistance generated between a terminal of the first oscillating transistor and a terminal of the second oscillating transistor, wherein the VCO does not include a tunable resonator.

15. A VCO as claimed in claim 14, wherein the tunable resonator is one of: a varactor, a YIG resonator, a cavity-tuned resonator and a dielectric resonant oscillator (DRO).

16. A VCO as claimed in claim 14 wherein the first non-linear load comprises a diode.

17. A VCO as claimed in claim 14 wherein the second non-linear load comprises a diode.

18. A VCO as claimed in claim 14 wherein the first non-linear load comprises a diode-connected transistor.

19. A VCO as claimed in claim 14 wherein the second non-linear load comprises a diode-connected transistor.

20. A VCO as claimed in claim 14, wherein the terminals are respective collectors of the first and second oscillating transistors.

21. A VCO as claimed in claim 14, wherein the terminals are respective drains of the first and second oscillating transistors.

22. A VCO as claimed in claim 14, wherein the negative resistance is adapted to stabilize oscillation by reducing a closed-loop gain of the oscillator with an increasing amplitude of oscillation.
